(19) United States
(12) Patent Application Publication
(10) Pub. No.: US 2025/0140554 A1
(43) Pub. Date: May 1, 2025

(54) DIAMOND STRUCTURE AND METHOD OF FORMING A DIAMOND STRUCTURE

(71) Applicant: Advanced Diamond Holdings, LLC, Beltsville, MD (US)

(72) Inventor: John P. Ciraldo, Beltsville, MD (US)

(21) Appl. No.: 18/932,566

(22) Filed: Oct. 30, 2024

Related U.S. Application Data
(60) Provisional application No. 63/546,399, filed on Oct. 30, 2023.

(51) Int. Cl. H01L 21/02; C30B 25/18; C30B 29/04; C30B 29/10; C30B 29/38; C30B 33/12

(52) U.S. Cl. CPC H01L 21/02527; C30B 25/186; C30B 29/04; C30B 29/10; C30B 29/38; C30B 33/12; H01L 21/02491

(57) ABSTRACT

A method manufactures a diamond heterostructure and separates diamond wafers from the heterostructure. The method provides a single-crystal substrate. A first single-crystal sacrificial layer is epitaxially formed on the base. The first sacrificial layer includes niobium nitrate and/or titanium nitride. A first single-crystal diamond layer is epitaxially formed on the first sacrificial layer. A second single-crystal sacrificial layer is epitaxially formed on the first diamond layer. The second sacrificial layer includes niobium nitrate and/or titanium nitride. A second single-crystal diamond layer is epitaxially formed on the second sacrificial layer.

### PRIORITY

This patent application claims priority from provisional U.S. patent application No. 63/546,399, filed Oct. 30, 2023, entitled, “DIAMOND STRUCTURE AND METHOD OF FORMING A DIAMOND STRUCTURE,” and naming John Ciraldo as inventor, the disclosure of which is incorporated herein, in its entirety, by reference.

### GOVERNMENT RIGHTS

This invention was made with government support under contract no. HR00112490455 awarded by the Defense Advanced Research Projects Agency. The government has certain rights in the invention.

### FIELD OF THE INVENTION

Illustrative embodiments of the invention generally relate to diamond wafers and, more particularly, illustrative embodiments relate to large diameter diamond wafers.

### BACKGROUND OF THE INVENTION

Diamond has important uses as an ultra-wide bandgap semiconductor, thermal stabilizer for traditional semiconductor devices, enabler of quantum technologies, and more. However, realizing the use of diamond in these technologies relies on the ability to produce diamond as a single-crystal substrate in appropriate form factors, such as a 2-inch round wafer. While significant progress has been made in producing diamond at the necessary size scales to achieve this goal, finishing the material into an appropriate form factor remains challenging.

### SUMMARY OF VARIOUS EMBODIMENTS

In accordance with one embodiment of the invention, a method manufactures a diamond heterostructure and separates diamond wafers from the heterostructure. The method provides a single-crystal substrate. A first single-crystal sacrificial layer is epitaxially formed on the base. The first sacrificial layer includes niobium nitrate and/or titanium nitride. A first single-crystal diamond layer is epitaxially formed on the first sacrificial layer. A second single-crystal sacrificial layer is epitaxially formed on the first diamond layer. The second sacrificial layer includes niobium nitrate and/or titanium nitride. A second single-crystal diamond layer is epitaxially formed on the second sacrificial layer.

The diamond layers can be separated from sacrificial layers to produce free standing single-crystal diamonds. Illustrative embodiments use a gas etch to etch away at least a portion of a given sacrificial layer. The gas etch preferably comprises xenon difluoride. The gas etch may be provided in a pressurized chamber having a pressure of 0.75 ATM or less. However, in some embodiments, the pressure may go up to 5 ATM. The diamond heterostructure may be moved from a growth environment, such as a CVD chamber, to a gas etch bath/chamber.

The process may epitaxially form a given sacrificial layer on a previous diamond layer. The given sacrificial layer includes niobium nitrate and/or titanium nitride. The process may also epitaxially form a subsequent diamond layer on the subsequent sacrificial layer. This process may be repeated to form as desired to form more and more diamond layers on sacrificial layers. Accordingly, sacrificial layer formed from niobium nitrate and/or titanium nitride, and a diamond layer epitaxially formed on the sacrificial layer define a repeating unit of a heteroepitaxial super-lattice.

The first sacrificial layer may be epitaxially formed using atomic-layer deposition, physical vapor deposition, and/or chemical vapor deposition.

The first diamond layer may have a thickness of between about 10 and 1000 microns. The first diamond layer may have a width of between about 25 mm and about 250 mm. In various embodiments, the diamond layers are processed to define wafers having a width of greater than 25 mm and less than 210 mm, and a thickness of between about 10 microns and 1000 microns.

Illustrative embodiments include a hetero-diamond structure and/or diamond wafers formed using the processes described above.

In accordance with another embodiment, an apparatus includes a first sacrificial layer. The first sacrificial layer may be single-crystal and includes niobium nitrate and/or titanium nitride. The apparatus includes a first single-crystal diamond layer formed on the first sacrificial layer.

In various embodiments, the first single-crystal diamond layer has a width/diameter of greater than 25 mm. The first single-crystal diamond layer may have a width/diameter of less than 250 mm. The first single-crystal diamond layer may have a thickness of between about 100 microns and about 3 mm, and a width of between about 25 mm and about 250 mm. The first sacrificial layer may have a thickness of between 10 nanometers and 5 microns, and a width of between about 25 mm and about 250 mm.

In various embodiments, the apparatus includes a base comprising a single-crystal base material composition. The first sacrificial layer may be epitaxially formed on the base. The apparatus may also include a second sacrificial layer on the first diamond layer. The second sacrificial layer includes niobium nitrate and/or titanium nitride. A second single-crystal diamond layer may be on the second sacrificial layer.

In various embodiments, the apparatus may include transistors and/or other semiconductor devices built on the wafer. In some embodiments the wafer may be diced and packaged into integrated circuits. In various embodiments, the integrated circuits made us may have a power density of, for example, greater than 2 W/mm².

In accordance with another embodiment, a system fabricates large diamond wafers. The system includes a chemical vapor deposition chamber configured to deposit niobium nitrate and/or titanium nitride on a base. The chemical vapor deposition chamber is further configured to deposit single-crystal diamond on the sacrificial layer. The single-crystal diamond has a width of at least 25 mm. The system also includes a vacuum chamber coupled to a xenon difluoride source. The chamber has a gas delivery system configured to input the xenon difluoride into the chamber. The chamber also has a pressure control system configured to maintain a stable pressure.

The sacrificial layers may be deposited in the CVD chamber used to deposit diamond. Alternatively, the sacrificial layer may be deposited using a different chamber. In some embodiments, the pressure may be less than 0.75 atm. In some embodiments, the pressure may be between 0.5 atm and 5 atm. The system may further include a diamond structure. The diamond structure may have a first sacrificial layer. The first sacrificial layer may be single-crystal and includes niobium nitrate and/or titanium nitride. A first single-crystal diamond layer may be formed on the first sacrificial layer. The first single-crystal diamond layer may have a width of between about 20 mm and about 250 mm.

In accordance with another embodiment, a method fabricates diamond wafers by providing a substrate in a chemical vapor deposition chamber. A first sacrificial layer is formed on the base. The first sacrificial layer includes niobium nitrate and/or titanium nitride. A first diamond layer is formed on the first sacrificial layer. A second sacrificial layer is formed on the first diamond layer. The second sacrificial layer includes niobium nitrate and/or titanium nitride. A second diamond layer is formed on the second sacrificial layer.

The method may form a subsequent sacrificial layer on a previous diamond layer. Then a subsequent diamond layer may be formed on the subsequent sacrificial layer. This process may be repeated to form a plurality of diamond wafers as desired. The diamond layers may be polycrystalline, or they may be single-crystal. The single-crystal layers are epitaxially deposited. The substrate may be formed from diamond, silicon, sapphire, and/or magnesium oxide.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows a bulk diamond in accordance with illustrative embodiments.

FIG. 1B schematically shows a laser process for cutting the bulk diamond into wafers in accordance with illustrative embodiments.

FIG. 1C schematically shows free standing wafers after laser cutting of FIG. 1B.

FIG. 2 shows a process of forming diamond wafers in accordance with illustrative embodiments of the invention.

FIG. 3A schematically shows a heteroepitaxial diamond structure in accordance with illustrative embodiments.

FIG. 3B schematically shows the hetero-diamond structure within a vacuum chamber.

FIG. 3C shows the heterostructure of FIG. 3B as the gaseous etch etches the sacrificial layer.

FIG. 3D schematically shows the free-standing diamond layer forming individual diamond wafers after removal of the sacrificial layer in accordance with illustrative embodiments.

FIG. 3E schematically shows a top view of one of the wafers on FIG. 3D.

### DESCRIPTION OF ILLUSTRATIVE EMBODIMENTS

In illustrative embodiments, a synthetic diamond (e.g., lab grown) chemical vapor deposition fabrication process results in large diameter (e.g., 25 mm and above width) and high-quality (e.g., single crystal, low-defect, low point defect, low dislocation density, low stress) diamond wafer. To that end, a sacrificial layer or film is deposited onto a substrate (e.g., single crystal or polycrystalline). The sacrificial layer includes niobium nitrate (NbN) and/or titanium nitride (TiN). A diamond layer is grown on the sacrificial layer. This process can be repeated to form a super-lattice of sacrificial layers and diamond layers. Then, the sacrificial layer can be etched away using a gaseous etch, such as xenon difluoride (XeF2). Details of illustrative embodiments are discussed below.

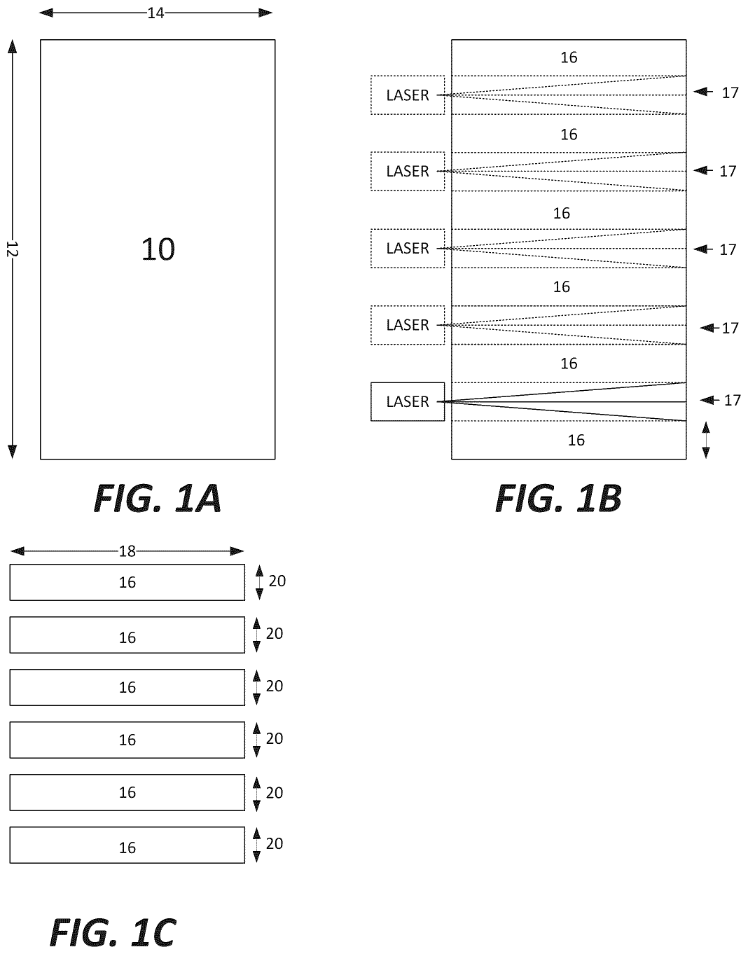

FIG. 1A schematically shows a bulk diamond 10 in accordance with illustrative embodiments. The bulk diamond 10 may be grown, for example, using homoepitaxial CVD growth or other methods. The bulk diamond 10 has a total thickness 12 or height 12 and a width 14. As shown in FIGS. 1B-1C, the bulk diamond 12 may be cut to form individual wafers 16. The wafers 16 generally have a width 18 that is the same as the width of the bulk diamond 12. Thickness 20 of the wafers 16 is generally based on the desired application, and thus, wafers 16 are cut as thick as desired. Generally, the wafers 16 may have a thickness 20 of between about 100 microns and about 3 mm.

FIG. 1B schematically shows a laser process for cutting the bulk diamond 10 into wafers 16 in accordance with illustrative embodiments. FIG. 1C schematically shows free standing wafers after laser cutting.

The inventor determined that laser cutting has a number of disadvantages for cutting diamond wafers 16 that make it particularly undesirable, particularly for larger wafers (e.g., 15 mm and greater). For example, laser defocusing and other challenges related to laser slicing increase the risk of thermal stress or cracking. High temperatures from the laser can induce stress within the bulk diamond 10 and wafers 16, resulting in cracks or microfractures. Microfractures or cracks from the laser can weaken the diamond structure, reduce its clarity, or even render the diamond wafer 16 unusable for some applications. The temperatures from the laser can also cause the diamond to convert to graphite (carbonization) or even vaporize as carbon dioxide. This process leads to material loss 17 and can affect the edge quality, potentially producing a rough or uneven cut. Carbonization can also lead to residue buildup on the cut surfaces, impacting clarity and smoothness, which is undesirable for the wafers 16.

These properties make cutting large diameter/width 18 wafers 16 difficult to cut. The material loss 17 can be rather large. For example, for a 500 micron thick 20 by 2 inches wide 18 wafer 16, it may be necessary to grow about 2 mm of bulk diamond 10 material, and about 1.5 mm of diamond can be lost when cutting with the laser (e.g., for wafers 16 having a width 18 of greater than 15 mm). As the desired wafer 16 width 18 becomes larger, the laser beam divergence becomes larger (shown in FIG. 1B), leading to more and more material loss 17. Advantageously, illustrative embodiments provide a process for producing large diameter/width 18 wafers 16 with minimal waste and without causing cracking of the diamond wafer 16.

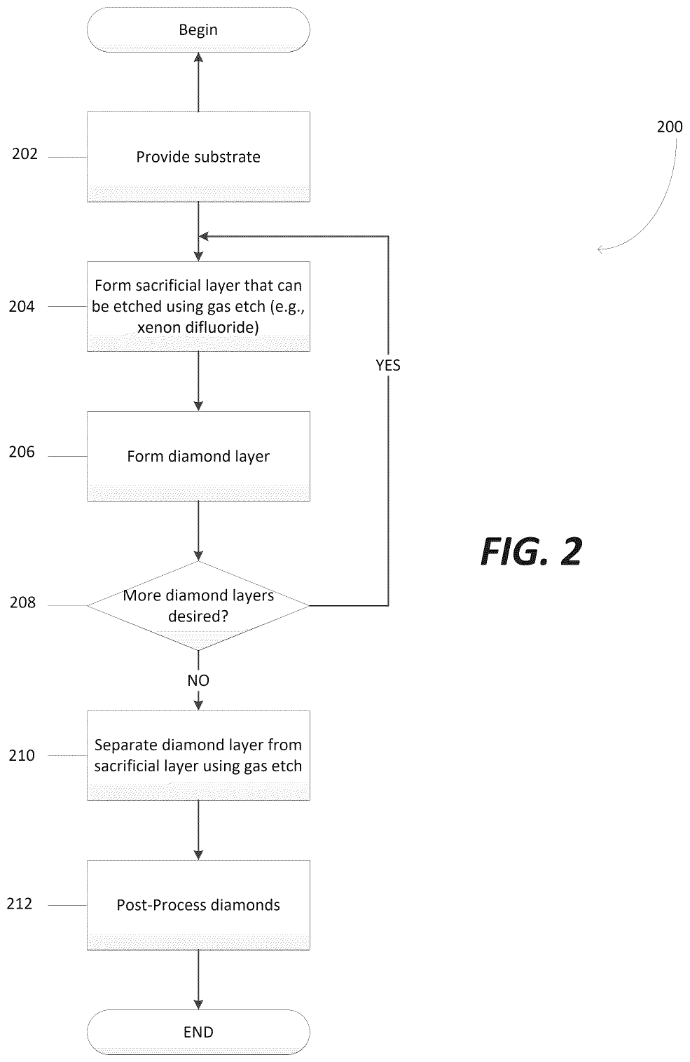

FIG. 2 shows a process of forming diamond wafers 16 in accordance with illustrative embodiments of the invention. It should be noted that this method is substantially simplified from a longer process that may normally be used. Accordingly, the method shown in FIG. 2 may have many other steps that those skilled in the art likely would use. In addition, some of the steps may be performed in a different order than that shown, or at the same time. Furthermore, some of these steps may be optional in some embodiments. Accordingly, the process 200 is merely exemplary of one process in accordance with illustrative embodiments of the invention. Those skilled in the art therefore can modify the process as appropriate.

In illustrative embodiments, at least part of the process is executed inside a furnace or other device (not shown) having a chamber with carefully controlled environmental conditions, such as prescribed pressures, temperatures, and environmental gasses.

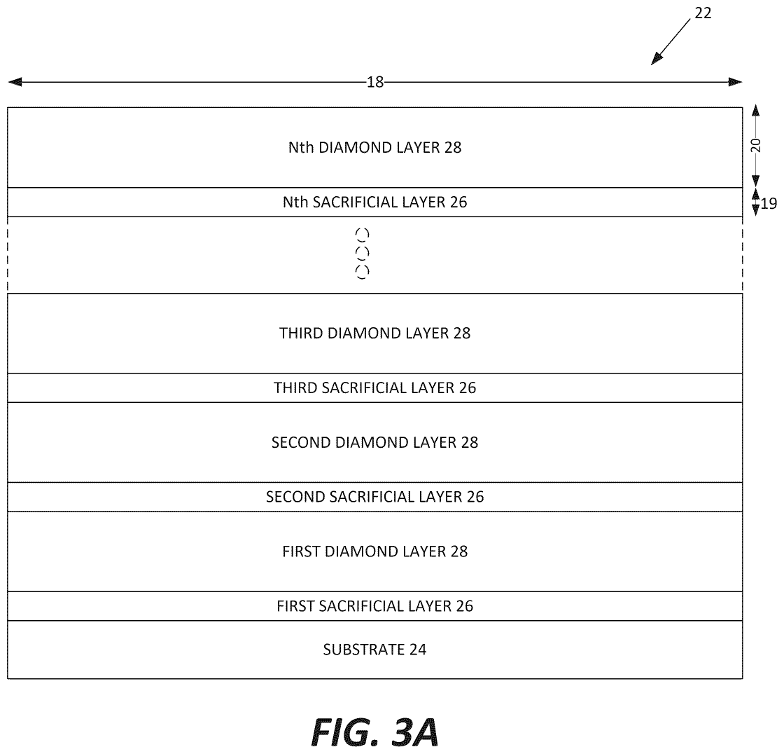

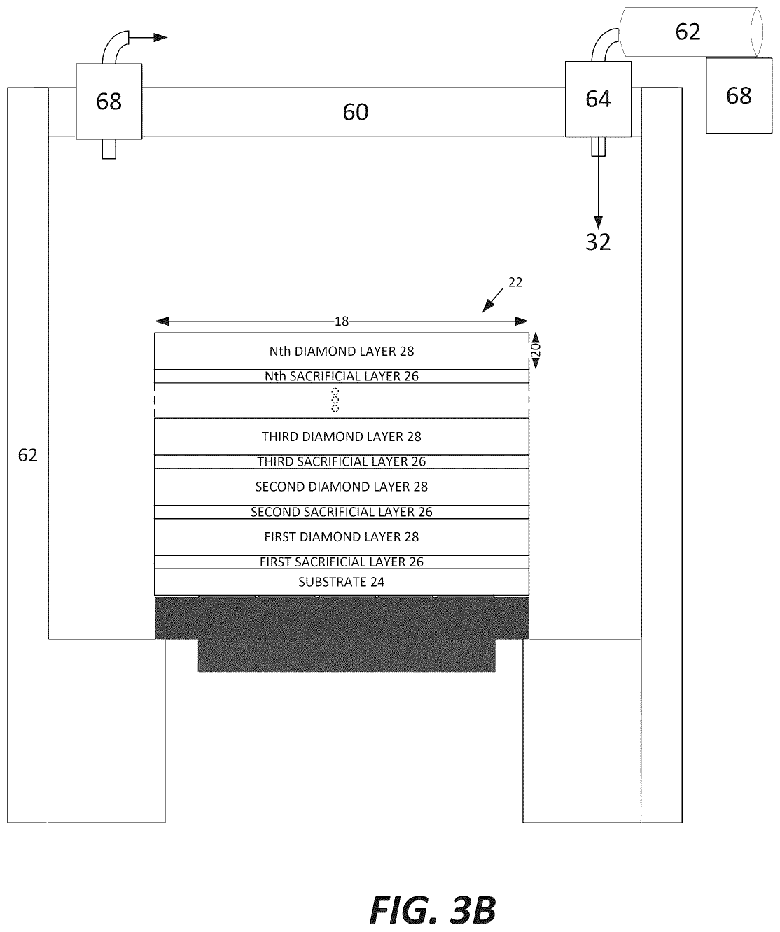

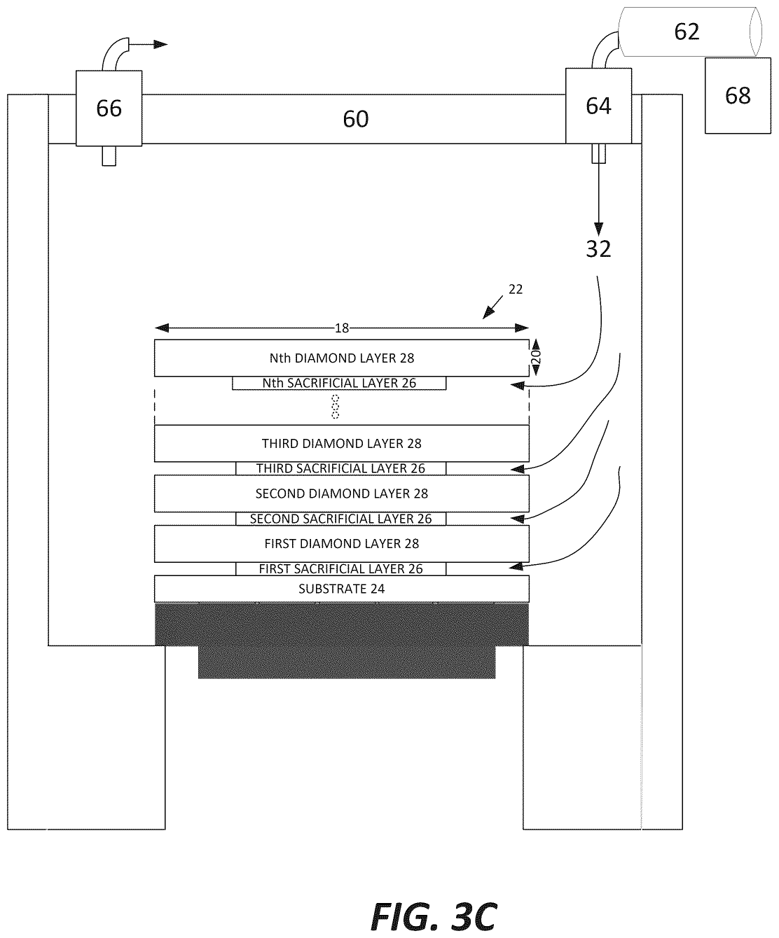

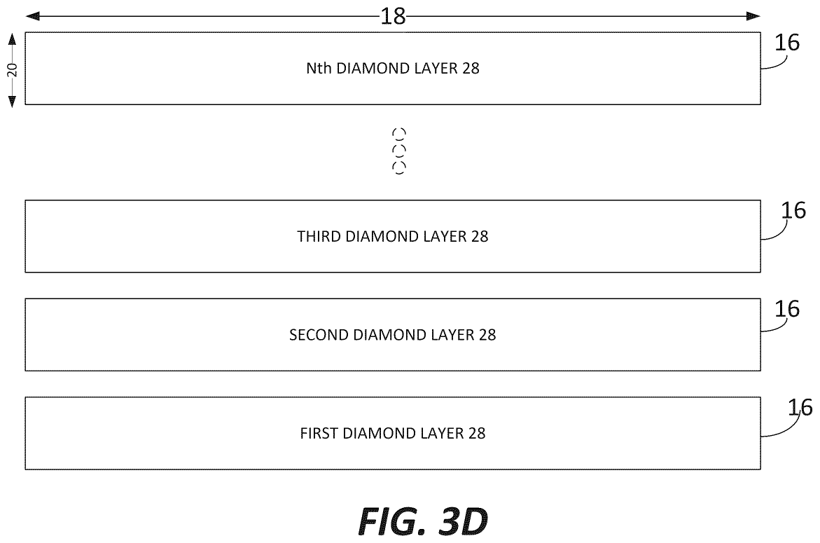

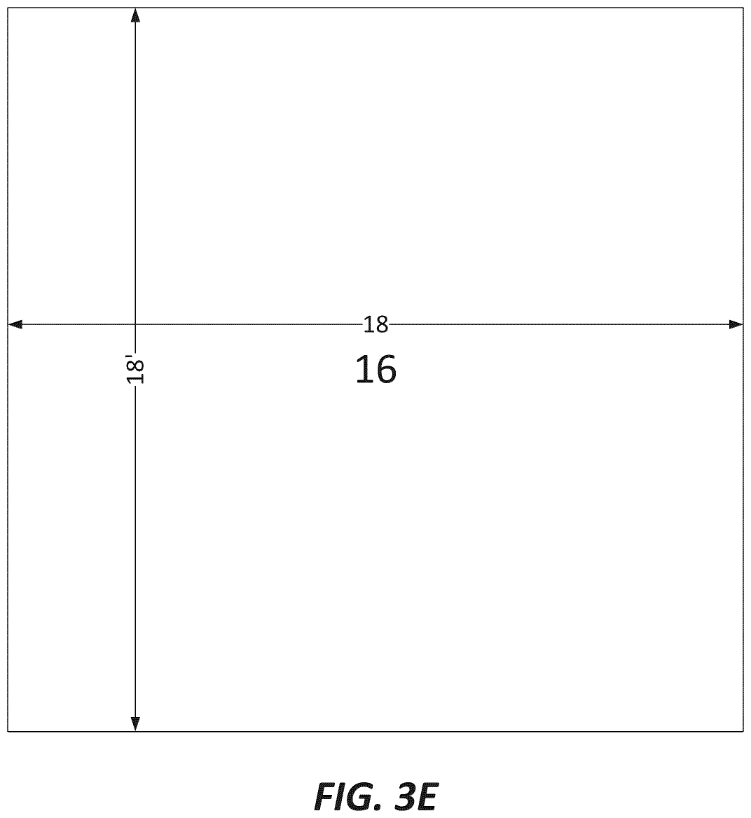

FIG. 3A schematically shows a heteroepitaxial diamond structure 22 in accordance with illustrative embodiments. In various embodiments, the diamond structure 22 may be formed using the process of FIG. 2. Therefore, for ease of discussion, the process of FIG. 2 may be discussed with reference to the structures shown in FIG. 3A-3E. The structure 22 advantageously allows for the growth and separation of considerably larger diamond wafers 16 without the aforementioned problems of laser cutting.

The process begins at step 202, which provides a base substrate 24 on which the first sacrificial layer 26 is to be deposited. The process of depositing or otherwise forming the sacrificial layer may begin with the preparation of a high-quality single crystal diamond substrate. In various embodiments, it is important to start with a clean and pristine diamond surface to ensure the effectiveness of the sacrificial layer 26 deposition. For example, the substrate 24 may be cleaned meticulously using solvents like acetone and isopropyl alcohol to remove any contaminants or organic residues. After cleaning, the diamond substrate 24 can be rinsed with deionized water and dried in a controlled environment to prevent any recontamination.

In some embodiments, the base 24 may be formed from, for example, single crystal diamond, sapphire, magnesium oxide, iridium, silicon, silicon carbide diamond, or combinations thereof. Those skilled in the art may select yet a different material for the base 24. Preferably, the base 24 has a single crystal/monocrystalline structure. This monocrystalline structure may be used to form monocrystalline diamond. However, various embodiments may also form polycrystalline diamond.

The process proceeds to step 204, which forms the sacrificial layer (e.g., the first sacrificial layer 26) that can be etched using xenon difluoride gas etch. In illustrative embodiments, the sacrificial film 26 is deposited onto a single crystal substrate 24. The film to be applied can be formed from niobium nitrate (NbN) and/or titanium nitride (TIN). The inventor determined that NbN and TiN have two advantages—the first is that both materials possess cubic lattice structures, thereby facilitating epitaxy on diamond and vice versa (epitaxy of diamond on NbN or TiN). Second, both may be etched by xenon difluoride in gaseous phase, facilitating easier removal of the sacrificial layer.

The choice of deposition method depends on the specific requirements of the application. Illustrative embodiments may deposit the sacrificial layer 26 by physical vapor deposition (PVD), chemical vapor deposition (CVD), and/or atomic layer deposition (ALD). PVD involves the physical transfer of material from a source to the substrate through processes like evaporation or sputtering. In contrast, CVD add ALD involve the chemical reaction of precursor gases on the substrate to form a layer.

After the sacrificial layer 26 is deposited onto the diamond substrate 24 using the chosen technique, it undergoes a curing or solidification process, if applicable. This step ensures the sacrificial layer 26 adheres firmly to the diamond surface 24.

In various embodiments, the sacrificial layer 26 includes a pseudomorphically grown portion. As known by those skilled in the art, pseudomorphic growth is a type of epitaxial growth that can occur in which a thin film (e.g., the sacrificial layer 26) grows on a substrate with a slightly different lattice constant, but the film 26 initially strains itself to match the lattice structure of the substrate 24. This creates a coherent interface without defects, maintaining atomic alignment despite lattice mismatch. However, this alignment is only maintained up to a certain critical thickness, beyond which the strain becomes too high, and the film may relax, often by forming dislocations or defects. However, various embodiments may have one or more sacrificial layers 26 that include a pseudomorphic grown portion. Advantageously, the pseudomorphic grown portion results in high quality diamond layers 28 and minimal loss from the heteroepitaxial growth process (e.g., less than 10-50 microns).

The process then proceeds to step 206, which forms the single-crystal diamond layer on the sacrificial layer. Specifically, the single crystal diamond layer 28 is deposited atop the sacrificial layer 26 to produce a continuous, crystalline diamond in the desired shape and thickness necessary for wafer 16 use. Preferably, the diamond is deposited using CVD to produce large dimension diamond (e.g., large diameter/width 18). In various embodiments, one or more of the deposited diamond layers 28 may each have a diameter/width 18 of about 20 mm to about 250 mm. Because the shape of the diamond layer 16 may be adjusted, it should be understood that reference to the width 18 can also be used to refer to the diameter 18 in case of a substantially circular layer. Furthermore, in the case of a substantially rectangular layer, the term width 18 also applies to a length of the layer.

The process then proceeds to step 208, which asks if more diamond layers 28 are desired? If yes, the process returns to step 204, which forms the sacrificial layer. However, this time, the sacrificial layer 26 is deposited on the diamond layer 28. For example, the second sacrificial layer 26 is deposited on the first diamond layer 28 shown in FIG. 3A. The process then proceeds to step 206, which forms the diamond layer on the sacrificial layer. This process may be repeated as many times as desired.

Specifically, steps 204-206 may be repeated in a periodic structure. For example, the process may be repeated using the process of U.S. Pat. No. 11,198,950 related to a “superlattice,” the disclosure of which is incorporated herein, in its entirety, by reference. However, it is not necessary for each sacrificial layer 26 to be of an identical thickness, although they can be identical thicknesses. Similarly, it is not necessary for each diamond layer 28 to be of an identical thickness, although they can be identical thicknesses. Accordingly, the process may be repeated to achieve an Nth sacrificial layer 26 and an Nth diamond layer 28.

After the desired number of diamond layers have been formed, the process proceeds to step 210, which separates the diamond layer 28 from the sacrificial layer using the gas etch. Preferably, the sacrificial layer 26 is dissolvable by an etch in a gaseous phase that does not affect the diamond 28. To that end, the finished diamond structure 22 may be soaked in a chamber containing xenon difluoride 32. When the sacrificial films 26 are dissolved, the diamond wafers 16 are separated in the process.

FIG. 3B schematically shows the hetero-diamond structure 22 within a vacuum chamber 60. Although a single hetero-diamond structure 22 is shown within the chamber 60, one or more structures 22 may be processed simultaneously or sequentially.

The chamber 60 can be equipped with a xenon difluoride source 62, a temperature control system, and a vacuum pump 66. The vacuum is created to ensure a controlled environment, preventing unwanted reactions with ambient gases. Preferably, the vacuum chamber is configured to maintain pressure within the chamber 60 at less than 1 atm. In some embodiments, the chamber 60 may include a pressure control system configured to maintain a stable pressure. The pressure in the chamber may be about 50 Torr or greater. Some embodiments may use pressures of than 0.5 atmosphere for consistent and safe etching. By maintaining the pressure below 1 atmosphere, illustrative embodiments advantageously provide a safe manufacturing environment in case of a gas leak (e.g., pulls outside gas into the chamber 60 rather than causing gas to leak out of the chamber).

Despite the safety concern, the inventor believes that as diamond technology improves to the point where larger and larger diameter diamond layers 28 are formed (e.g., greater than 250 mm diameter 18), it may be advantageous to increase the pressure within the chamber 60 so the xenon difluoride 32 reaches all the way through the sacrificial layer 26 (e.g., for layers 26 having a width of greater than 100 mm). Accordingly, various embodiments may pressurize the chamber 60 with greater than 0.75 atm (e.g., 0.75 atm to 5 atm).

The xenon difluoride source 62 may then be heated by a heater 68 to release gaseous XeF2. A gas including XeF2 may pass through input 64 into the chamber. The gas chamber 62 has a gas input 66 configured to input gas 32 into the chamber 62. The input 64 may optionally include a pump or other gaseous injection system configured to position the XeF2 within the chamber. Furthermore, it should be understood that the shape, arrangement, and position of the chamber 60, heater 68, vacuum 60, gaseous source 62 and gas input 66 are merely illustrative, and not intended to limit various embodiments.

FIG. 3C shows the heterostructure 22 of FIG. 3B as the gaseous etch 32 etches the sacrificial layer 26. The inventor determined that there is a challenge with chemical separation of large diameter layers 28. In particular, the inventor found that layer 28 separation is difficult because it is difficult to get the chemical etch all the way to the center of the sacrificial layer 26. The inventor determined that it is easier to get the etch 32 to reach all the way through large diameter structures if the etch 32 is in gaseous phase than if the etch is in a liquid phase. Further advantages include that the sacrificial layer 26 can be smaller when using a gaseous etch 32 (e.g., because not as much space is needed for gaseous etch to reach throughout the entire sacrificial layer). Accordingly, illustrative embodiments may use lower thickness 19 sacrificial layers 26 than those used in the art. For example, illustrative embodiments can have the thickness 19 of the sacrificial layer between about 10 nm and about 1 micron. However, the larger sizes (e.g., closer to 1 micron) are no longer pseudomorphically grown. Accordingly, various embodiments preferably keep the sacrificial layer thickness 19 to greater than 1 nm but less than 100 nm.

Xenon difluoride 32 is highly reactive with many materials, including silicon and certain polymers, making it an effective sacrificial layer removal agent. Importantly, xenon difluoride 32 is not reactive with the diamond. Thus, a gaseous etch 32 is introduced into the chamber that reacts with the sacrificial layers 26 but not with the diamond layers 28. When introduced into the vacuum chamber, XeF2 gas reacts with the sacrificial layer 26, causing it to undergo a chemical reaction and convert into volatile byproducts. During this process, the XeF2 gas selectively removes the sacrificial layer 26 while leaving the diamond layer 28 intact. The sacrificial layer 26 removal process should be carefully monitored to ensure that it proceeds as planned. Parameters like temperature, pressure, and exposure time may need to be adjusted based on the specific sacrificial material and layer thickness.

After the sacrificial layer is removed the process proceeds to step 212 which post-processes the individual diamond wafers 16. FIG. 3D schematically shows the free-standing diamond layers 28 forming individual diamond wafers 16 after removal of the sacrificial layer 26 in accordance with illustrative embodiments. In various embodiments, the diamond wafers 16 may have a width of between about 25 mm and about 210 mm. The diamond wafers 16 may have the same thickness as the diamond layers 28 described herein.

FIG. 3E schematically shows a top view of one of the wafers 16 on FIG. 3D. As used herein, the width 18 is also used to refer to the length 18′ of the substrate. As shown in FIG. 3E, the width 18 and the length 18′ define an area of the diamond layer 28. Thus, when illustrative embodiments are described as having a particular width 18 or a particular diameter 18, it should be understood that the description of the width 18 or diameter 18 also applies to the length 18′. For example, the wafer 16 having width 18′ of greater than 25 mm may also have the length 18′ of greater than 25 mm. Similarly, when the wafer 16 has width 18 less than 200 mm, the length 18′ also may be less than 200 mm. For convenience, discussion of the length 18′ is not repeated herein. Furthermore, discussion of width 18 may also apply to a diameter 18 for a substantially circular diamond layer 28 and/or finished wafer 16.

It should also be understood that the edges of various diamond layers 28 may be trimmed when processing the wafer 16. Thus, the diamond layer 28 may have a slightly larger size than the finished wafer 16. In general, it is desirable to produce diamond layers 28 that achieve 2″ to 4″ diameter wafers 16. However, various embodiments can produce larger and small wafers 16, corresponding to the size of the diamond layers 28 described herein.

To process the diamond wafers 16, the chamber 60 can be vented and the diamond wafers 16 removed safely. The final step often involves thorough cleaning and inspection of the diamond substrate to ensure that no residue or contaminants remain. As described earlier, the post-processing can be minimal given the high quality of the diamond achieved via the above-described process.

Illustrative embodiments forming the sacrificial layer 26 from NbN and/or TiN, and removing of the sacrificial layer 26 using XeF2 provide a number of advantages. Specifically, illustrative embodiments enable the separation of large-diameter diamond (e.g., 25 mm in diameter) without cracking or significant damage to the diamond structure. Illustrative embodiments may use the laser to cut diamond wafers having a width 18 of less than 25 mm. Preferably, illustrative embodiments produce wafers 16 having dimensions of between about 2″ and about 4″ to run on current semiconductor tooling.

Illustrative embodiments also include the intermediate and final structures, as they would provide potential practical benefits in production. Samples may be sent to a polisher or end use with the sacrificial layer intact to be removed onsite. Because the diamond wafers 16 left over from the separation process are near finished shape (because of reduction in damage as compared to other wafer forming techniques), polishing is greatly simplified, reducing time, cost, and material waste.

The wafers 16 may also be prepared and processed for the fabrication of semiconductor devices and integrated circuits. Accordingly, the wafer 16 may be taken for metallization and pad formation. Semiconductor devices may be formed on the wafer 16, and the wafer 16 may be diced and packaged. Accordingly, illustrative embodiments may also include the steps of cleaning (e.g., in a chemical bath), oxidation, photolithography, etching, doping, deposition of portions of the integrated circuit, metallization, dicing, and/or packaging. Illustrative embodiments may also include electronic devices and integrated circuits formed using the large diamond wafer 16. As used in this specification and the claims, the singular forms “a,” “an,” and “the” refer to plural referents unless the context clearly dictates otherwise. For example, reference to “the layer” in the singular includes a plurality of layers, and reference to “the wafer” in the singular includes one or more wafers and equivalents known to those skilled in the art. Thus, in various embodiments, any reference to the singular includes a plurality, and any reference to more than one component can include the singular. While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain using no more than routine experimentation, many equivalents to the specific inventive embodiments described herein.

It is, therefore, to be understood that the foregoing embodiments are presented by way of example only and that, within the scope of the appended claims and equivalents thereto, inventive embodiments may be practiced otherwise than as specifically described and claimed. Illustrative embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure. Disclosed embodiments, or portions thereof, may be combined in ways not listed above and/or not explicitly claimed. Thus, one or more features from variously disclosed examples and embodiments may be combined in various ways. For example, it is to be understood that the present disclosure contemplates that, to the extent possible, one or more features of any embodiment can be combined with one or more features of any other embodiment.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Although the above discussion discloses various exemplary embodiments of the invention, it should be apparent that those skilled in the art can make various modifications that will achieve some of the advantages of the invention without departing from the true scope of the invention.

What is claimed is:

1. A method of fabricating diamond wafers comprising:
providing a single-crystal substrate;
epitaxially forming a first single-crystal sacrificial layer on the base, the first sacrificial layer comprising niobium nitrate and/or titanium nitride;
epitaxially forming a first single-crystal diamond layer on the first sacrificial layer;
epitaxially forming a second single-crystal sacrificial layer on the first diamond layer, the second sacrificial layer comprising niobium nitrate and/or titanium nitride; and
epitaxially forming a second single-crystal diamond layer on the second sacrificial layer.

2. The method of claim 1, further comprising separating diamond layers from sacrificial layers to produce free standing single-crystal diamonds.

3. The method of claim 2, wherein separating comprises using a gas etch to etch away at least a portion of a given sacrificial layer.

4. The method of claim 3, wherein the gas etch comprises xenon difluoride.

5. The method of claim 3, wherein the gas etch is provided in a pressurized chamber having a pressure of above 50 Torr but less than 570 Torr.

6. The method of claim 1, further comprising repeating the steps of:
epitaxially forming a given sacrificial layer on a previous diamond layer, the given sacrificial layer comprising niobium nitrate and/or titanium nitride; and
epitaxially forming a subsequent diamond layer on the subsequent sacrificial layer.

7. The method of claim 1, wherein a sacrificial layer, comprising niobium nitrate and/or titanium nitride, and a diamond layer epitaxially formed on the sacrificial layer define a repeating unit of a heteroepitaxial super-lattice, wherein epitaxially forming the first sacrificial layer comprises using atomic-layer deposition, physical vapor deposition, and/or chemical vapor deposition.

8. The method as defined by claim 1 wherein the first diamond layer has a thickness of between about 10 and 1000 microns.

9. The method as defined by claim 1 wherein the first diamond layer has a width of between about 25 mm and about 250 mm.

10. The method as defined by claim 4, further comprising forming semiconductor devices on the wafer, dicing the diamond wafer, and packaging integrated circuits having the diced diamond wafer.

11. The apparatus formed by claim 4.

12. An apparatus comprising:
a first sacrificial layer, the first sacrificial layer being single-crystal and comprising niobium nitrate and/or titanium nitride;
a first single-crystal diamond layer formed on the first sacrificial layer.

13. The apparatus of claim 12, wherein the first single-crystal diamond layer has a width of greater than 25 mm.

14. The apparatus of claim 12, wherein the first single-crystal diamond layer has a width of less than or equal to 250 mm.

15. The apparatus of claim 12, wherein the first sacrificial layer has a thickness of between 10 nanometers and 5 microns, and a width of between about 25 mm and about 250 mm.

16. The apparatus of claim 12, wherein the first single-crystal diamond layer has a thickness of between about 100 microns and about 3 mm, and a width of between about 25 mm and about 250 mm.

17. The apparatus of claim 12, further comprising a base comprising a single-crystal base material composition, the first sacrificial layer being epitaxially formed on the base.

18. The apparatus of claim 12, further comprising:
a second sacrificial layer on the first diamond layer, the second sacrificial layer comprising niobium nitrate and/or titanium nitride; and
a second single-crystal diamond layer on the second sacrificial layer.

19. A system for fabricating large diamond wafers comprising:
a chemical vapor deposition chamber configured to deposit niobium nitrate and/or titanium nitride on a base, the chemical vapor deposition chamber further configured to deposit single-crystal diamond on the base, the single-crystal diamond having a width of at least 25 mm;
a vacuum chamber configured to have a xenon difluoride gas therein, the chamber having a gas delivery system configured to input xenon difluoride into the chamber, the chamber also having a pressure control system configured to maintain a stable pressure of less than 5 atmosphere.

20. The system of claim 19, further comprising:
a diamond structure comprising:
a first sacrificial layer, the first sacrificial layer being single-crystal and comprising niobium nitrate and/or titanium nitride, and
a first single-crystal diamond layer formed on the first sacrificial layer, the first single-crystal diamond layer have a width of between about 20 mm and about 200 mm.

21. A method of fabricating diamond wafers comprising:
providing a substrate in a chemical vapor deposition chamber;
forming a first sacrificial layer on the base, the first sacrificial layer comprising niobium nitrate and/or titanium nitride;
forming a first diamond layer on the first sacrificial layer;
forming a second sacrificial layer on the first diamond layer, the second sacrificial layer comprising niobium nitrate and/or titanium nitride; and
forming a second diamond layer on the second sacrificial layer.

22. The method of claim 21, wherein the first diamond layer and the second diamond layer are polycrystalline.

23. The method of claim 21, wherein the substrate is formed from diamond, silicon, sapphire, and/or magnesium oxide.

24. The method of claim 21, further comprising separating the diamond layer from the sacrificial layer to form free-standing diamond layers, post-processing the diamond layers to define wafers having a width of greater than 25 mm and less than 210 mm, and a thickness of between about 10 microns and 1000 microns.

25. An integrated circuit formed by claim 10.
